(19) United States
(12) Patent Application Publication
(10) Pub. No.: US 2005/0035455 A1
(43) Pub. Date: Feb. 17, 2005

(54) Device with low-k dielectric in close proximity thereto and its method of fabrication

(76) Inventors: Chenming Hu, Alamo, CA (US); Denny Tang, Hsinchu (TW); Horng-Huei Tseng, Hsinchu (TW)

Correspondence Address: BIRCH STEWART KOLASCH & BIRCH, PO BOX 747, FALLS CHURCH, VA, 22040-0747, US

(21) Appl. No.: 10/640,312

(22) Filed: Aug. 14, 2003

(51) Int. Cl. H01L 21/44

(52) U.S. Cl. 257/758

(57) ABSTRACT

A semiconductor device with a low-k material in close proximity thereto and its fabrication method. The device includes a gate electrode overlying a substrate. An electrically conductive plug is provided immediately adjacent to the gate electrode and making electrical contact to the device. A low-k dielectric material is disposed in the space between the gate electrode and the electrically conductive plug whereby reducing the parasitic capacitance. Thus, higher density of devices can be formed without decreasing operating speed.

### BACKGROUND OF THE INVENTION

1. Field of the Invention

The invention relates to semiconductor manufacturing, and more particularly to a semiconductor device with a low-k (low dielectric constant) material in close proximity thereto and a method of manufacturing the same.

2. Description of the Related Art

Semiconductor device geometries have dramatically decreased in size since such devices were first introduced several decades ago. Today's wafer fabrication plants are routinely producing devices having 0.18 μm and even 0.15 μm feature sizes, and tomorrow's plants will soon be producing devices with even smaller geometries.

However, various problems are caused as a result of the reduction in size of the elements. For example, the shortening of the channel length achieves the effect of lowering the channel resistance on the one hand but, on the other, gives rise to the problem that a short-channel effect is brought about. Further, as a result of the reduction in size of the elements, the ratios of the various parasitic components become relatively high. For example, in the case of a MOS transistor, the junction capacitance of the source/drain is brought to such a high ratio that it affects the operating speed.

An unrecognized problem is the increase of the parasitic capacitance between the gate electrode and the adjacent conductive plug used to connect the transistor, which however, will become a bottleneck in ultra-miniaturization of devices according to the present inventors' investigation. In addition, the parasitic capacitance between two adjacent contact plugs also increases because of their close proximity.

Considerable work has been done to reduce the junction capacitance of the source/drain, but has not addressed the problems associated with the parasitic capacitance between the gate electrode and the conductive plug or of that between adjacent plugs. For example, in U.S. Pat. No. 6,383,883, a method is taught using double implantation to reduce the junction capacitance of the source/drain. In U.S. Pat. No. 6,198,142, a metal oxide semiconductor transistor with minimal junction capacitance is described. Still another method for reducing junction capacitance is taught in U.S. Pat. No. 6,570,217, in which a cavity is provided in the portion of the silicon substrate which lies beneath the channel region of the MOS transistor.

The present inventors recognize the need for reducing the parasitic capacitance between the gate electrode and the contact plug and that between two adjacent contact plugs to accommodate the ultra-miniaturization of devices. This becomes exceptionally important as the RC (resistance X capacitance) delay becomes increasingly critical in ultra deep sub-micron devices with feature lengths of 0.13 μm or beyond.

### SUMMARY OF THE INVENTION

A broad object of the invention is to provide a semiconductor device having an ultra deep sub-micron feature length and its method of fabrication.

Another object of the invention is to provide an ultra deep sub-micron device and its method of fabrication whereby scaling issues of the parasitic capacitance between the gate and the contact plug are addressed.

A further object of the invention is to provide an ultra deep sub-micron device and its method of fabrication whereby scaling issues of the parasitic capacitance between two adjacent contact plugs are addressed.

To achieve the above and other objects, a low-k dielectric material is disposed in close proximity to the semiconductor device. Specifically, the low-k dielectric material is disposed between the gate electrode and the conductive plug or between two closely spaced conductive plugs to reduce the parasitic capacitance. Although low-k dielectric is commonly used between interconnects to reduce the RC delay, using it at the above positions is never suggested. At the present time, the insulating material for the above positions is silicon oxide or related silicate glasses such as borophosphosilicate (BPSG) with k value between 3.9-4.2.

According to an aspect of the invention, there is provided a semiconductor device including: a substrate; a device having a gate electrode overlying the substrate; an electrically conductive plug immediately adjacent to the gate electrode and making electrical contact to the device; and a low-k dielectric material disposed in the space between the gate electrode and the electrically conductive plug.

According to another aspect of the invention, there is provided a semiconductor device including: a substrate; two closely spaced devices on the substrate, isolated with an isolation element therebetween; two adjacent electrically conductive plugs disposed between the two closely spaced devices and respectively making electrical contact to each device; and a low-k dielectric material disposed in the space between the two adjacent contact plugs.

According to a further aspect of the invention, there is provided a method of manufacturing a semiconductor device, including the steps of: providing a device having a gate electrode overlying a substrate; forming a low-k dielectric layer in close proximity to the device; forming a contact opening adjacent to the gate electrode through the low-k dielectric layer; and forming an electrically conductive plug in the opening to make electrical contact to the device.

According to a still further aspect of the invention, there is provided a method of manufacturing a semiconductor device, including the steps of: providing two closely spaced devices on a substrate, isolated with an isolation element therebetween; forming a low-k dielectric layer overlying the two closely spaced devices; and forming two adjacent electrically conductive plugs through the low-k dielectric layer between the two closely spaced devices to respectively make electrical contact to each of the devices.

### DESCRIPTION OF THE DRAWINGS

For a better understanding of the present invention, reference is made to a detailed description to be read in conjunction with the accompanying drawings, in which:

FIG. 1 is a cross-section showing a semiconductor device according to the first embodiment of the invention, in which a low-k dielectric insulator is disposed between the gate electrode and the adjacent contact plug to reduce the parasitic capacitance; and

FIG. 2 is a cross-section showing a semiconductor device according to the second embodiment of the invention, in which a low-k dielectric insulator is disposed between the two adjacent contact plugs to reduce the parasitic capacitance.

### REFERENCE NUMERALS IN THE DRAWINGS

100 substrate
110 shallow trench isolation
120, 120a, 120b MOS transistor
122 gate electrode
124 source/drain region
126 gate dielectric
128 spacer
130 buffer layer
140 low-k dielectric layer
150, 150a, 150b contact opening
160, 160a, 160b electrically conductive plug
d1 spacing between gate 122 and plug 160
d2 spacing between plug 160a and plug 160b

### DETAILED DESCRIPTION OF THE INVENTION

In this specification, expressions such as “overlying the substrate”, “above the layer”, or “on the film” simply denote a relative positional relationship with respect to the surface of the base layer, regardless of the existence of intermediate layers. Accordingly, these expressions may indicate not only the direct contact of layers, but also, a non-contact state of one or more laminated layers. By use of the term “low dielectric constant” or “low k” herein, is meant a dielectric constant (k value) which is less than the dielectric constant of a conventional silicon oxide. Preferably, the dielectric constant of the low k is less than about 3.3 and more preferably less than about 2.8.

First Embodiment

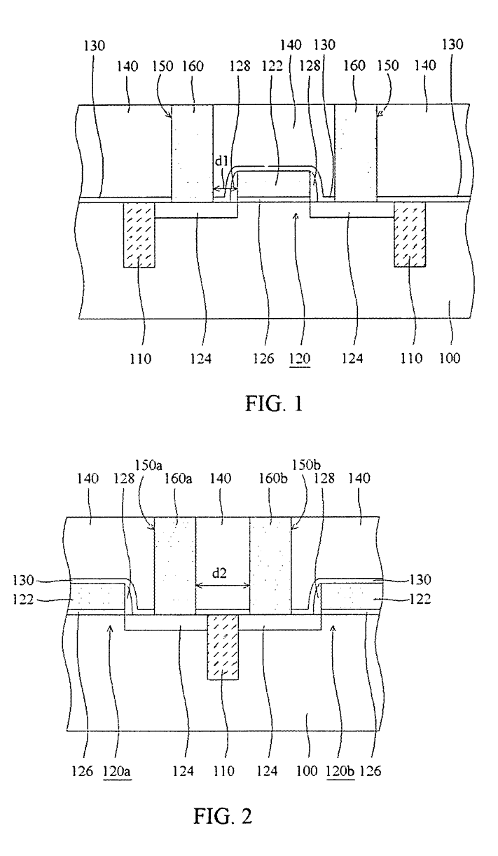

A preferred embodiment of the present invention is now described in detail with reference to FIG. 1.

FIG. 1 is a schematic cross-section showing a semiconductor substrate 100 having a field effect MOS transistor 120 with a low-k dielectric layer 140 in close proximity thereto. The preferred substrate 100 is composed of P type single-crystal silicon with a <100> crystallographic orientation, and may contains defective semiconductor lattice in the channel region of the MOS transistor 120 to increase drive current. For example, a SiGe epitaxial layer may be grown for mobility enhancement.

The MOS transistor 120 is formed in an active device area isolated by isolation elements such as the well-known shallow trench isolation (STI) structures 110 as shown. The MOS transistor includes a gate electrode 122 overlying the substrate with a gate dielectric 126 interposed therebetween, and a pair of source/drain regions 124 formed in the substrate oppositely adjacent to the gate electrode 126. The gate electrode 122 preferably consists of doped polysilicon and refractory metal silicide, and insulating sidewall spacers 128 may be formed on the sidewalls of the gate electrode 122. The process details for forming such a field effect transistor are well known and will not be described here; however, since the present invention is particularly advantageous for devices having ultra deep sub-micron feature lengths, preferred size features of the MOS transistor 120 will now be described. The height of the gate electrode 122 is preferably less than about 3,000 Å end more preferably less than about 2,500 Å. The width of the gate electrode 122 is preferably less than 0.1 μm. The effective thickness of the gate dielectric 126 is preferably equivalent to a conventional layer of silicon oxide having a thickness of about 25 Å or less. The gate dielectric 126 may be comprised of conventional silicon oxide or high-k dielectrics such as Y₂O₃, La₂O₃, Al₂O₃, ZnO₂, HfO₂, or combinations of silicon oxide and high-k dielectrics. The width the isolation element 110 is less than about 1500 Å

Next, as a main feature and a key aspect of the present invention, a low-k dielectric layer 140 is formed in close proximity to the MOS transistor 120. Preferably, the low-k dielectric layer is present within 200 nm, and more preferably 150 nm from the gate electrode 122 and the source/drain regions 124. The use of low-k dielectric is not new in semiconductor manufacturing, but forming a low-k dielectric so close to a MOS transistor is never suggested. This low-k material 140 serves to reduce the parasitic capacitance between the gate electrode 122 and the adjacent conductive plug 160, thereby reducing the RC delay and resulting in an improved performance of the MOS transistor. Accordingly, the low-k material 140 should at least substantially fill the space (>70%) between the gate electrode 122 and the conductive plug 160. Typically and preferably, the low-k dielectric layer 140 is blanketly deposited overlying the entire substrate surface including the MOS transistor 120 as a pre-metal dielectric (PMD), and then a through plug is formed down to the source/drain regions so as to be embedded in the low-k dielectric.

The low-k material 140 can be a carbon-containing material or a carbon/oxygen-containing material. Suitable low-k materials include but are not limited to inorganic CVD (Chemical Vapor Deposition) materials such as fluorosilicate glass (FSG), Black Diamond (trade name, carbon-doped silica developed by Applied Materials); organic spin-on materials such as polyimide organic polymer, polyarylene ether organic polymer commonly known as PAE-2™ and FLARE™, parylene organic polymer and fluorinated analogs thereof; spin-on-glass (SOG) materials such as hydrogen silsesquioxane (HSQ), carbon bonded hydrocarbon silsesquioxane, and carbon bonded fluorocarbon silsesquioxane. For example, the FSG can be deposited by low pressure CVD using TEOS (tetraethyl-ortho-silicate) and by introducing a fluorine-containing dopant gas such as carbon tetrafluoride (CF₄). The low-k dielectric layer 140 is deposited to a thickness between about 3,000-12,000 Å and preferably has a planar upper surface.

In a more preferred embodiment, a conformal buffer layer 130 is deposited lining the substrate surface and the MOS transistor 120 before forming the low-k dielectric layer 140. The buffer layer is preferably a silicon/nitrogen-containing dielectric having a thickness between about 200-2000 Å. The buffer layer 130 serves several functions: (1) it provides a diffusion barrier against out-diffusion of the dopants that may be present in the low-k dielectric layer; (2) it improves adhesion between the underlying substrate and the low-k dielectric layer; and (3) it serves as an etch stop when etching the contact opening in the low-k dielectric layer. When serving as a diffusion barrier, the material is preferably chosen from SiOC, SiNC, or Si-rich oxide. When serving as an adhesion layer, the material is preferably chosen from SiOC, SiNC, SiC, or Si-rich oxide. When serving as an etch stop layer, the material is preferably chosen from SiON, SiN, or Si-rich oxide.

Following the formation of the low-k dielectric layer 140, contact openings 150 are defined down to the source/drain regions 124 on the substrate using known lithography technology and anisotropic etching methods. When etching the contact openings 150, the buffer layer 130, if any, can serve as an etch stop to avoid damage to the underlying device. Although the aspect ratio of the contact opening 130 can vary depending on the design rule, the present invention is particularly suitable for those not less than 5. Typically and preferably, the contact opening 150 has a width between about 100 and 1,000 Å.

Subsequently, conductive plugs 160 are formed in the contact openings 150 to electrically connect to the source/drain regions 124 of the MOS transistor 120. The conductive plugs 160 can be formed of electrically conductive materials including but not limited to metal, metal compound, metal alloy, doped polysilicon, polycides, although copper and copper alloys are particularly preferred. It can be formed by overfilling the contact opening and removing the conductive material outside of the contact opening by etch back or chemical mechanical polishing (CMP).

For example, a conformal metal barrier layer (not shown) such as tantalum, titanium, tungsten, tantalum nitride, titanium nitride, or tungsten nitride is deposited overlying the substrate surface including the contact openings 150, and then an electrically conductive material 160 is deposited on the barrier metal by chemical vapor deposition (CVD), physical vapor deposition (PVD), or electrochemical deposition (ECD) to substantially fill the contact openings 150. Thereafter, the metal barrier layer and the conductive material 160 are etched back or polished by use of the CMP until the low-k dielectric layer 140 is exposed, thus forming the conductive plugs 160 embedded in the contact openings 150. Alternatively, the above metal barrier layer can be replaced by a dielectric barrier (not shown) provided only on the sidewalls of the contact openings 150. It can be formed by depositing a substantially conformal dielectric layer over the entire substrate surface followed by anisotropic etch back. Preferable materials for the dielectric barrier include silicon oxide, silicon nitride, carbon-doped silicon oxide, carbon-doped silicon nitride, carbon/nitride doped silicon oxide, silicon carbide, or combinations thereof.

As shown in FIG. 1, the parasitic capacitance between the gate electrode 122 and the conductive plug 160 is substantially reduced by the low-k dielectric layer 140. In future products having minimum feature sizes of 0.13 μm or even smaller, the spacing d1 between the gate electrode 122 and the conductive plug 160 will also decrease to less than about 2,000 Å. Since the parasitic capacitance (Cp) varies inversely with spacing (d), when d decreases, the Cp increases. With the present invention, by reducing the dielectric constant (k) of the dielectric layer 140, the spacing d1 can be further reduced without increasing the parasitic capacitance. For example, if the dielectric constant k is reduced by 50% (e.g. k is reduced from 4 to 2), then the spacing d1 can also be decreased by 50% without increasing Cp.

Second Embodiment

FIG. 2 shows another embodiment of the invention, in which like numbers from the first described embodiment are utilized where appropriate. Two closely spaced field effect MOS transistors 120a, 120b are formed on a semiconductor substrate using known processes, isolated by a STI 110 therebetween. After a conformal buffer layer 130 (optional) and a blanket low-k dielectric layer 140 as in the first embodiment are formed, two contact openings 150a, 150b are defined through the low-k dielectric layer 140 between the two transistors to respectively expose one of the source/drain regions 124 of each transistor. Thereafter, electrically conductive materials are embedded in the contact openings 150a, 150b, thereby forming two adjacent conductive plugs 160a, 160b to respectively make electrical contact to each of the MOS transistors 120a, and 120b.

As shown in FIG. 2, the low-k dielectric material 140 reduces the parasitic capacitance between the two adjacent conductive plugs 160a, 160b. In future products having minimum feature sizes of 0.13 μm or even smaller, the spacing d2 between adjacent conductive plugs of closely spaced transistors will also decrease to less than about 2,000 Å. By forming a low-k dielectric material between the closely spaced conductive plugs, the spacing d2 can be decreased without increasing the parasitic capacitance.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

1. A semiconductor device, comprising:
a substrate;
a device having a gate electrode overlying the substrate;
an electrically conductive plug adjacent to the gate electrode and making electrical contact to the device;
a buffer layer overlying the device and the substrate; and
a low-k dielectric material disposed in the space between the gate electrode and the electrically conductive plug.

2. The semiconductor device as claimed in claim 1, wherein the device comprises a MOS transistor.

3. The semiconductor device as claimed in claim 1, further comprising a gate dielectric having an effective thickness less than 25 Å interposed between the gate electrode and the substrate.

4. The semiconductor device as claimed in claim 1, wherein the substrate comprises defective semiconductor lattice.

5. (Canceled)

6. The semiconductor device as claimed in claim 1, wherein the substrate comprises silicon and germanium.

7. The semiconductor device as claimed in claim 1, wherein the height of the gate electrode is less than about 3,000 Å.

8. The semiconductor device as claimed in claim 1, wherein the width of the gate electrode is less than about 1,000 Å.

9. The semiconductor device as claimed in claim 1, wherein the dielectric constant of the low-k dielectric material is less than about 3.3.

10. The semiconductor device as claimed in claim 1, wherein the dielectric constant of the low-k dielectric material is less than about 2.8.

11. The semiconductor device as claimed in claim 1, wherein the low-k dielectric material comprises fluorosilicate glass (FSG), Black Diamond, an organic spin-on material, a spin-on-glass (SOG) material, an inorganic CVD material, or combinations thereof.

12. The semiconductor device as claimed in claim 1, wherein the low-k dielectric material comprises a carbon-containing material.

13. The semiconductor device as claimed in claim 1, wherein the low-k dielectric material comprises a carbon/oxygen-containing material.

14. The semiconductor device as claimed in claim 1, wherein the spacing between the gate electrode and the electrically conductive plug is less than about 2,000 Å.

15. (Canceled)

16. The semiconductor device as claimed in claim 1, wherein the buffer layer is a silicon/nitrogen-containing film.

17. The semiconductor device as claimed in claim 1, wherein the buffer layer functions as an etch stop layer and comprises a material of nitride doped silicon oxide, silicon nitride, or silicon-rich oxide.

18. The semiconductor device as claimed in claim 1, wherein the buffer layer functions as a diffusion barrier and comprises a material of carbon doped silicon oxide, carbon-doped silicon carbide, silicon carbide, or silicon-rich oxide.

19. The semiconductor device as claimed in claim 1, wherein the buffer layer functions as an adhesion layer and comprises a material of carbon doped silicon oxide, carbon-doped silicon nitride, silicon carbide, or silicon-rich oxide.

20. The semiconductor device as claimed in claim 1, wherein the width of the electrically conductive plug is between about 100 and 1000 Å.

21. The semiconductor device as claimed in claim 1, wherein the low-k dielectric material substantially fills the space between the gate electrode and the electrically conductive plug.

22. A semiconductor device, comprising:
a substrate;
a device having a gate electrode overlying the substrate;
a buffer layer overlying the substrate and the device;
a low-k dielectric layer disposed in close proximity to the device and overlying the buffer layer, wherein the low-k dielectric layer and the buffer layer define a contact opening adjacent to the gate electrode; and
an electrically conductive plug embedded in the opening and making electrical contact to the device.

23. The semiconductor device as claimed in claim 22, wherein the device comprises a MOS transistor.

24. The semiconductor device as claimed in claim 22, further comprising a source/drain region in the substrate adjacent to the gate electrode whereby the electrically conductive plug is disposed thereupon to make electrical contact to the device.

25. The semiconductor device as claimed in claim 22, wherein the low-k dielectric layer is present within 200 nm from the gate electrode.

26. The semiconductor device as claimed in claim 22, wherein the low-k dielectric layer is present within 200 nm from the source/drain region.

27. The semiconductor device as claimed in claim 22, further comprising a gate dielectric having an effective thickness less than about 50 Å interposed between the gate electrode and the substrate.

28. The semiconductor device as claimed in claim 22, wherein the substrate comprises defective semiconductor lattice.

29. (Canceled)

30. The semiconductor device as claimed in claim 22, wherein the substrate comprises silicon and germanium.

31. The semiconductor device as claimed in claim 22, wherein the height of the gate electrode is less than about 3,000 Å.

32. The semiconductor device as claimed in claim 22, wherein the width of the gate electrode is less than about 1000 Å.

33. The semiconductor device as claimed in claim 22, wherein the dielectric constant of the low-k dielectric layer is less than about 3.3.

34. The semiconductor device as claimed in claim 22, wherein the dielectric constant of the low-k dielectric layer is less than about 2.8.

35. The semiconductor device as claimed in claim 22, wherein the low-k dielectric layer comprises fluorosilicate glass (FSG), Black Diamond, an organic spin-on material, a spin-on-glass (SOG) material, an inorganic CVD material, or combinations thereof.

36. The semiconductor device as claimed in claim 22, wherein the low-k dielectric layer comprises a carbon-containing material.

37. The semiconductor device as claimed in claim 22, wherein the low-k dielectric layer comprises a carbon/oxygen-containing material.

38. The semiconductor device as claimed in claim 22, wherein the spacing between the gate electrode and the electrically conductive plug is less than about 2000 Å.

39. (Canceled)

40. The semiconductor device as claimed in claim 22, wherein the buffer layer is a silicon/nitrogen-containing film.

41. The semiconductor device as claimed in claim 22, wherein the buffer layer functions as an etch stop layer and comprises a material of nitride doped silicon oxide, silicon nitride, or silicon-rich oxide.

42. The semiconductor device as claimed in claim 22, wherein the buffer layer functions as a diffusion barrier and comprises a material of carbon-doped silicon oxide, carbon-doped silicon nitride, silicon carbide, or silicon-rich oxide.

43. The semiconductor device as claimed in claim 22, wherein the buffer layer functions as an adhesion layer and comprises a material of nitride doped silicon oxide, carbon doped silicon nitride, or silicon-rich oxide.

44. The semiconductor device as claimed in claim 22, wherein the width of the electrically conductive plug is between about 100-1000 Å.

45. A semiconductor device, comprising:
a substrate;
a device having a gate electrode overlying the substrate and a pair of source/drain regions formed in the substrate oppositely adjacent to the gate electrode, wherein the width of the gate electrode is less than about 1000 Å;
a buffer layer overlying the device and the substrate;
a blanket low-k dielectric layer overlying the device and the substrate, wherein the low-k dielectric layer and the buffer layer define a contact opening to one of the source/drain regions; and
an electrically conductive plug embedded in the opening and making electrical contact to one of the source/drain regions, wherein the spacing between the electrically conductive plug and the gate electrode is less than about 2000 Å.

46. The semiconductor device as claimed in claim 45, wherein the low-k dielectric layer is present within 200 nm from the gate electrode.

47. The semiconductor device as claimed in claim 45, wherein the low-k dielectric layer is present within 200 nm from the source/drain region.

48. The semiconductor device as claimed in claim 45, further comprising a gate dielectric having an effective thickness less than about 25 Å interposed between the gate electrode and the substrate.

49. The semiconductor device as claimed in claim 45, wherein the substrate comprises defective semiconductor lattice.

50. (Canceled)

51. The semiconductor device as claimed in claim 45, wherein the substrate comprises silicon and germanium.

52. The semiconductor device as claimed in claim 45, wherein the height of the gate electrode is less than about 3,000 Å.

53. The semiconductor device as claimed in claim 45, wherein the dielectric constant of the low-k dielectric layer is less than about 3.3.

54. The semiconductor device as claimed in claim 45, wherein the dielectric constant of the low-k dielectric layer is less than about 2.8.

55. The semiconductor device as claimed in claim 45, wherein the low-k dielectric layer comprises fluorosilicate glass (FSG), Black Diamond, an organic spin-on material, a spin-on-glass (SOG) material, an inorganic CVD material, or combinations thereof.

56. The semiconductor device as claimed in claim 45, wherein the low-k dielectric layer comprises a carbon-containing material.

57. The semiconductor device as claimed in claim 45, wherein the low-k dielectric layer comprises a carbon/oxygen-containing material.

58. The semiconductor device as claimed in claim 45, wherein the spacing between the gate electrode and the electrically conductive plug is less than about 2000 Å.

59. (Canceled)

60. The semiconductor device as claimed in claim 45, wherein the buffer layer is a silicon/nitrogen-containing film.

61. The semiconductor device as claimed in claim 45, wherein the buffer layer functions as an etch stop layer and comprises a material of nitride doped silicon oxide, silicon nitride, or silicon-rich oxide.

62. The semiconductor device as claimed in claim 45, wherein the buffer layer functions as a diffusion barrier and comprises a material of carbon doped silicon oxide, carbon doped silicon nitride, silicon carbide, or silicon-rich oxide.

63. The semiconductor device as claimed in claim 45, wherein the buffer layer functions as an adhesion layer and comprises a material of carbon doped silicon oxide, carbon doped silicon nitride, or silicon-rich oxide.

64. The semiconductor device as claimed in claim 45, wherein the width of the electrically conductive plug is between about 100-1000 Å.

65. A semiconductor device, comprising:
a substrate;
two closely spaced devices on the substrate, isolated with an isolation element therebetween;
two adjacent electrically conductive plugs disposed between the two closely spaced devices and respectively making electrical contact to each of the devices;
a low-k dielectric material having a dielectric constant less than about 2.8 disposed in the space between the two adjacent contact plugs; and
a buffer layer disposed between the substrate and the low-k dielectric material.

66. The semiconductor device as claimed in claim 65, wherein the devices comprise two closely spaced MOS transistors.

67. The semiconductor device as claimed in claim 65, wherein the isolation element is a trench isolation element.

68. The semiconductor device as claimed in claim 65, wherein the substrate comprises defective semiconductor lattice.

69. (Canceled)

70. The semiconductor device as claimed in claim 65, wherein the substrate comprises silicon and germanium.

71. (Canceled)

72. (Canceled)

73. The semiconductor device as claimed in claim 65, wherein the low-k dielectric material comprises an organic spin-on material.

74-75. (Canceled)

76. The semiconductor device as claimed in claim 65, wherein the spacing between the two adjacent electrically conductive plugs is less than about 2000 Å.

77. The semiconductor device as claimed in claim 65, wherein the width of each of the electrically conductive plugs is between about 100-1000 Å.

78. The semiconductor device as claimed in claim 65, wherein the low-k dielectric material substantially fills the space between the two electrically conductive plugs.

79. The semiconductor device as claimed in claim 65, wherein the width the isolation element is less than about 1500 Å.

80. A method of manufacturing a semiconductor device, comprising the steps of:
providing a device having a gate electrode overlying a substrate;
forming a low-k dielectric layer in close proximity to the device;
forming a contact opening adjacent to the gate electrode through the low-k dielectric layer; and
forming an electrically conductive plug in the opening to make electrical contact to the device.

81. The method as claimed in claim 80, wherein the device comprises a MOS transistor.

82. The method as claimed in claim 81, wherein the device further comprises a source/drain region in the substrate adjacent to the gate electrode whereby the electrically conductive plug is disposed thereupon to make electrical contact to the device.

83. The method as claimed in claim 80, further comprising forming a buffer layer overlying the device and the substrate prior to forming the low-k dielectric layer.

84. The method as claimed in claim 83, wherein the buffer layer is a Si/N-containing film.

85. The method as claimed in claim 83, wherein the buffer layer functions as a diffusion barrier and comprises a material of SiOC, SiNC, SiC, or Si-rich oxide.

86. The method as claimed in claim 83, wherein the buffer layer functions as an adhesion layer and comprises a material of SiOC, SiNC, or Si-rich oxide.

87. The method as claimed in claim 83, wherein the buffer layer functions as an adhesion layer and comprises a material of SiOC, SiNC, or Si-rich oxide.

88. The method as claimed in claim 80, wherein the low-k dielectric layer is present within 200 nm from the gate electrode.

89. The method as claimed in claim 82, wherein the low-k dielectric layer is present within 200 nm from the source/drain region.

90. The method as claimed in claim 80, wherein the device further comprising a gate dielectric having an effective thickness less than about 25 Å interposed between the gate electrode and the substrate.

91. The method as claimed in claim 80, wherein the substrate comprises defective semiconductor lattice.

92. The method as claimed in claim 80, wherein the substrate comprises silicon.

93. The method as claimed in claim 80, wherein the substrate comprises silicon and germanium.

94. The method as claimed in claim 80, wherein the height of the gate electrode is less than about 3,000 Å.

95. The method as claimed in claim 80, wherein the width of the gate electrode is less than about 1000 Å.

96. The method as claimed in claim 80, wherein the dielectric constant of the low-k dielectric layer is less than about 3.3.

97. The method as claimed in claim 80, wherein the dielectric constant of the low-k dielectric layer is less than about 2.8.

98. The method as claimed in claim 80, wherein the low-k dielectric layer comprises fluorosilicate glass (FSG), Black Diamond, an organic spin-on material, a spin-on-glass (SOG) material, an inorganic CVD material, or combinations thereof.

99. The method as claimed in claim 80, wherein the low-k dielectric layer comprises a carbon-containing material.

100. The method as claimed in claim 80, wherein the low-k dielectric layer comprises a carbon/oxygen-containing material.

101. The method as claimed in claim 80, wherein the spacing between the gate electrode and the electrically conductive plug is less than about 2000 Å.

102. The method as claimed in claim 80, wherein the width of the electrically conductive plug is between about 100-1000 Å.

103. The method as claimed in claim 80, wherein the low-k dielectric layer is blanketly formed overlying the substrate and the device.

104. A method of manufacturing a semiconductor device, comprising the steps of:
providing two closely spaced devices on a substrate, isolated with an isolation element therebetween;
forming a low-k dielectric layer overlying the two closely spaced devices; and
forming two adjacent electrically conductive plugs through the low-k dielectric layer between the two closely spaced devices to respectively make electrical contact to each of the devices.

105. The method as claimed in claim 104, wherein the devices comprise two closely spaced MOS transistors.

106. The method as claimed in claim 104, wherein the isolation element is a trench isolation element.

107. The method as claimed in claim 104, wherein the substrate comprises defective semiconductor lattice.

108. The method as claimed in claim 104, wherein the substrate comprises silicon.

109. The method as claimed in claim 104, wherein the substrate comprises silicon and germanium.

110. The method as claimed in claim 104, wherein the dielectric constant of the low-k dielectric material is less than about 3.3.

111. The method as claimed in claim 104, wherein the dielectric constant of the low-k dielectric material is less than about 2.8.

112. The method as claimed in claim 104, wherein the low-k dielectric material comprises fluorosilicate glass (FSG), Black Diamond, an organic spin-on material, a spin-on-glass (SOG) material, an inorganic CVD material, or combinations thereof.

113. The method as claimed in claim 104, wherein the low-k dielectric material comprises a carbon-containing material.

114. The method as claimed in claim 104, wherein the low-k dielectric material comprises a carbon/oxygen-containing material.

115. The method as claimed in claim 104, wherein the spacing between the two adjacent electrically conductive plugs is less than about 200 nm.

116. The method as claimed in claim 104, wherein the width of each of the electrically conductive plugs is between about 100-1000 Å.

117. The method as claimed in claim 104, wherein the width the isolation element is less than about 1500 Å.

118. The method as claimed in claim 104, further comprising forming a buffer layer overlying the device and the substrate prior to forming the low-k dielectric layer.

119. The method as claimed in claim 118, wherein the buffer layer is a Si/N-containing film.

120. The method as claimed in claim 118, wherein the buffer layer functions as a diffusion barrier and comprises a material of SiOC, SiNC, SiC, or Si-rich oxide.

121. The method as claimed in claim 118, wherein the buffer layer functions as an adhesion layer and comprises a material of SiOC, SiNC, or Si-rich oxide.

122. The method as claimed in claim 118, wherein the buffer layer functions as an adhesion layer and comprises a material of SiOC, SiNC, or Si-rich oxide.

123. The method as claimed in claim 104, wherein the low-k dielectric layer is blanketly formed overlying the devices, the substrate, and the isolation element.

124. The semiconductor device as claimed in claim 65, wherein the buffer layer is a silicon/nitrogen-containing film.

125. The semiconductor device as claimed in claim 65, wherein the buffer layer functions as an etch stop layer and comprises a material of nitride doped silicon oxide, silicon nitride, or silicon-rich oxide.

126. The semiconductor device as claimed in claim 65, wherein the buffer layer functions as a diffusion barrier and comprises a material of carbon doped silicon oxide, carbon doped silicon nitride, silicon carbide, or silicon-rich oxide.

127. The semiconductor device as claimed in claim 65, wherein the buffer layer functions as an adhesion layer and comprises a material of carbon doped silicon oxide, carbon doped silicon nitride, or silicon-rich oxide.

128. The semiconductor device as claimed in claim 1, wherein the buffer layer has a thickness between about 200-2000 Å

129. The semiconductor deice as claimed in claim 22, wherein the buffer layer has a thickness between about 200-2000 Å.

130. The semiconductor device as claimed in claim 45, wherein the buffer layer has a thickness between about 200-2000 Å.

131. The semiconductor device as claimed in claim 65, wherein the buffer layer has a thickness between about 200-2000 Å.

132. A semiconductor device, comprising:
a substrate;
a device having a gate electrode overlying the substrate;
a low-k dielectric layer having a dielectric constant less than about 2.8 disposed in close proximity to but not contacting the gate electrode, wherein the low-k dielectric layer defines a contact opening adjacent to the gate electrode; and
an electrically conductive plug embedded in the opening and making electrical contact to the device.

133. The semiconductor device as claimed in claim 132, wherein the spacing between the gate electrode and the electrically conductive plug is less than about 2,000 Å.

134. A semiconductor device, comprising:
a substrate;
a device having a pair of source/drain regions formed in the substrate oppositely adjacent to the device;
a low-k dielectric layer having a dielectric constant less than about 2.8 disposed in close proximity to but not contacting the source/drain regions, wherein the low-k dielectric layer defines a contact opening to one of the source/drain regions; and
an electrically conductive plug embedded in the opening and making electrical contact to the device.

135. A semiconductor device, comprising:
a substrate;
a device having a gate electrode overlying the substrate;
a low-k dielectric layer having a dielectric constant less than about 2.8 disposed in close proximity to but not contacting the gate electrode at a distance about 20-150 nm therefrom, wherein the low-k dielectric layer defines a contact opening adjacent to the gate electrode; and
an electrically conductive plug embedded in the opening and making electrical contact to the device.

136. The semiconductor device as claimed in claim 135, wherein the spacing between the gate electrode and the electrically conductive plug is less than about 2,000 Å.

137. A semiconductor device, comprising:
a substrate;
a device having a pair of source/drain regions formed in the substrate oppositely adjacent to the device;
substrate oppositely adjacent to the device;
a low-k dielectric layer having a dielectric constant less than about 2.8 disposed in close proximity to but not contacting the source/drain regions at a distance about 20-150 nm therefrom, wherein the low-k dielectric layer defines a contact opening to one of the source/drain regions; and
an electrically conductive plug embedded in the opening and making electrical contact to the device.
